(19) United States
(12) Patent Application Publication
(10) Pub. No.: US 2007/0295968 A1
(43) Pub. Date: Dec. 27, 2007

(54) Electroluminescent device with high refractive index and UV-resistant encapsulant

(76) Inventors: Kheng Leng Tan, Penang (MY); Janet Bee Yin Chua, Perak (MY); Kee Yean Ng, Penang (MY)

Correspondence Address: Kathy Manke;Avago Technologies Limited, 4380 Ziegler Road, Fort Collins, CO, 80525, US

(21) Appl. No.: 11/476,519

(22) Filed: Jun. 27, 2006

(51) Int. Cl. H01L 33/00; H01L 31/12; H01L 27/15; H01L 29/26

(52) U.S. Cl. 257/79

(57) ABSTRACT

An encapsulant containing nanoparticles that improve the heat and UV resistance properties of electroluminescent devices. The nanoparticles that are suspended in the encapsulant may be either oxides or non-oxides and may include SiO₂, TiO₂, Al₂O₃, ZrO₂, Ti, TiB₂, TiC, and TiN. The nanoparticles may range in size from 5 to 165 nm in diameter. The encapsulant containing nanoparticles may be used in an electroluminescent device by being deposited in a concave base cavity to cover a light source, such as a light-emitting diode (“LED”), positioned in the concave base cavity, and may also be applied in the form of a conformal coating that covers the light source. An electroluminescent device utilizing the encapsulant containing nanoparticles and a method of producing such a device is also provided.

### BACKGROUND OF THE INVENTION

Light emitting diodes (“LEDs”) are, in general, miniature semiconductor devices that employ a form of electroluminescence resulting from the electronic excitation of a semiconductor material to produce visible light. Initially, the use of these devices was limited mainly to display functions on electronic appliances and the colors emitted were red and green. As the technology has improved, LEDs have become more powerful and available in a wide spectrum of colors.

With the fabrication of the first blue LED in the early 1990's, emitting light at the opposite end of the visible light spectrum from red, the possibility of creating virtually any color of light was opened up. With the capability to produce the primary colors, red, green, and blue (i.e., the RGB color model), with LED devices, there is now the capability to produce virtually any color of light, including white light. With the capability of producing white light, there is now the possibility of using LEDs for illumination in place of incandescent and fluorescent lamps, including use in outdoor lighting applications. The advantages of using LEDs for illumination is that they are far more efficient than conventional lighting, are rugged and very compact, and can last much longer than incandescent or fluorescent light bulbs or lamps.

White light can be made in different ways: by mixing reds, greens, and blues; by using an ultraviolet (“UV”) LED to stimulate a white phosphor; or by using a blue-emitting diode that excites a yellow-emitting phosphor embedded in an epoxy dome, where the combination of blue and yellow makes a white-emitting LED. Also, by combining a white phosphor LED with multiple amber LEDs, a range of different whites can be created.

In a typical configuration, an LED may be positioned in a concave base cavity adapted to provide an initial focus for the light output from the LED. The LED may be provided with anode and cathode bonding wires communicating with conductive leads that place the LED in communication with an electrical circuit for supplying a bias voltage to the LED. LEDs are typically encapsulated in an optically clear epoxy resin material intended to protect the LED from external contaminants and from being physically damaged or dislodged during assembly and use, to provide mechanical support and thermal management, and sometimes to form part of a lens system for further focusing the light output of the LED. Epoxy resins are often selected as the encapsulant because of their material properties, including hardness, resistance to chemicals, good adhesion to diverse materials, and optical properties.

However, along with light output, LED devices also generate heat. Despite typical design features of LED devices, including those summarized above, LED devices are commonly prone to damage caused by the buildup of heat generated from within the devices, as well as heat from sunlight in the case of outside lighting applications. Although metallized LED substrates are useful design elements that can be incorporated in LED devices and can serve to dissipate heat, these elements are often inadequate to maintain reasonably moderate temperatures in the devices. Excessive heat buildup can nevertheless cause deterioration of the materials used in the LED devices, such as encapsulants for the LED. Epoxy and silicone polymers, commonly used in LED encapsulant formulations, generally are poor heat conductors and are not sufficiently resistant to the high temperatures that often are generated inside LED devices during operation. These polymers can develop substantially reduced light transmissivity as they undergo heat degradation caused by such high temperatures. This reduced light transmissivity can increase absorbance by the LED devices themselves of light at wavelengths that are intended to be included in light output from the devices. This light absorbance may be more pronounced at near-ultra-violet wavelengths, and can cause commensurate declines in light output quality and intensity from an LED device.

Moreover, in the case of white light diodes that generate emission by utilizing broad-spectrum phosphors that are optically excited by near-violet or UV radiation, there may be even faster degradation of the packaging materials, i.e., the epoxy around the diode used to encapsulate the light emitting device, due to the high photon energy that can cause chemical-bond cracks and a structural breakdown of the epoxy material. This results in luminance (“Lv”) degradation, that is, less light output, over time as the phosphor/epoxy material is subjected to the UV radiation from the UV LED.

One approach to improve the heat dissipation properties of LEDs is through the use of silicone as the encapsulant. Silicone (or more accurately, a “polysiloxane co-polymer”) is both heat- and UV-stable and has a refractive index range from 1.38 to 1.60. Ideally, the refractive index of the encapsulant will be close to that of the semiconductor. However, the refractive index of a semiconductor in an LED is usually approximately 2.5. Consequently, there is reduction in the maximum light that can be extracted from the semiconductor.

Epoxy with added antioxidants and UV inhibitors may also be used to minimize the UV effects on yellowing, both from sunlight heat and specific UV wavelengths. Although these antioxidants and UV inhibitors have a better refractive index than that of silicone and reduce yellowing, their effectiveness may be reduced over time, leaving the encapsulant susceptible to damage from sunlight and specific UV wavelengths.

Consequently, there is a continuing need to provide new encapsulants for use in electroluminescent devices that have a better capability to dissipate heat and resist UV radiation in order to protect against degradation of the elements of the device.

### SUMMARY

An encapsulant for use in electroluminescent devices containing light sources, which may include LEDs, that has improved heat-resistant and UV-resistant properties, is disclosed. The encapsulant may include nanoparticles suspended in an epoxy resin or a silicone polymer, where the nanoparticles are in a range of 5-165 nanometers (“nm”) in diameter. The nanoparticles may be selected from groups of either oxides or non-oxides, where the oxides include silica (SiO₂), titania (TiO₂), alumina (Al₂O₃), zirconia (ZrO₂), etc., and the non-oxides contain pure metals or metal borides, carbides and nitrides, such as titanium and its combinations (Ti, TiB₂, TiC, and TiN). The nanoparticles may be present in a concentration less than 1.0% of the silicone matrix.

In an example implementation, the selected nanoparticles may be suspended in the encapsulant, which may then be utilized in the electroluminescent device in various forms to cover a light source, including the encapsulant being applied in a concave base cavity or throughout the entire package where a dome or shell covers the package. The encapsulant may also be applied in the form of conformal coatings that may be applied over the light source in thin layers. A method of producing such an electroluminescent device is also disclosed.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 shows a cross-sectional side view illustrating an example of an implementation of an electroluminescent device utilizing an LED as a light source (an “LED device”) having an encapsulant containing nanoparticles filling a concave base cavity in which an LED is attached.

FIG. 2 shows a cross-sectional side view illustrating another example of an implementation of an LED device having a dome covering an LED attached to a concave base cavity where the dome is filled with an encapsulant containing nanoparticles.

FIG. 3 shows a cross-sectional side view illustrating another example of an implementation of an LED device having a dome covering an LED attached to a substrate where the dome is filled with an encapsulant containing nanoparticles.

FIG. 4 shows a cross-sectional side view illustrating an example of an LED device that includes lead frames and a reflector cup wherein an encapsulant containing nanoparticles is applied to the reflector cup.

FIG. 5 shows a cross-sectional side view illustrating another example of an implementation of an LED device having a shell covering an LED attached to a substrate where the shell is filled with an encapsulant containing nanoparticles.

FIG. 6 shows a cross-sectional side view illustrating yet another example of an LED device that has lead frames and a reflector cup.

FIG. 7 shows a cross-sectional side view illustrating an example of an implementation of an LED device having a conformal coating containing nanoparticles applied to the inner surface of a concave base cavity in which an LED is attached.

FIG. 8 shows a cross-sectional side view illustrating an example of an implementation of an LED device that includes a conformal coating containing nanoparticles applied to the inner surface of a reflector cup.

FIG. 9 shows a cross-sectional side view illustrating an example of an implementation of an LED device having a conformal coating containing nanoparticles applied to an LED attached to a substrate positioned under a dome filled with an encapsulant.

FIG. 10 shows a cross-sectional side view illustrating an example of an implementation of an LED device having a conformal coating containing nanoparticles applied to an LED attached to a substrate positioned under a shell filled with an encapsulant.

### DETAILED DESCRIPTION

In the following description of examples of implementations, reference is made to the accompanying drawings that form a part hereof, and which show, by way of illustration, specific implementations of the invention that may be utilized. Other implementations may be utilized and structural changes may be made without departing from the scope of the present invention.

In general, an electroluminescent device containing a light source, such as a light-emitting diode (“LED”), and utilizing an encapsulant that includes suspended nanoparticles that may improve the heat-resistant and ultraviolet (“UV”)-resistant properties of the electroluminescent device is disclosed. The encapsulant, which may be an epoxy resin, a silicone polymer, an acrylic, a urethane, or other suitable material, may include nanoparticles suspended in the selected encapsulant where the nanoparticles may range in size from 5 to 165 nm in diameter. In general, the nanoparticles may be selected from groups of either oxides or non-oxides, where the oxides include silica (SiO₂), titania (TiO₂), alumina (Al₂O₃), zirconia (ZrO₂), etc., and the non-oxides may contain pure metals or metal borides, carbides and nitrides, such as titanium and its combinations (Ti, TiB₂, TiC, TiN, etc.). As an example, SiO₂ nanoparticles may have an average particle size of 80-150 nm and TiO₂ may have an average particle size of 40-100 nm.

As an example, an electroluminescent device containing an LED as a light source (an “LED device”) may utilize the encapsulant in the LED device in various forms: for example, the encapsulant may be deposited in a concave base cavity or a reflector cup that holds the LED or throughout the entire LED device where a dome or shell covers the LED device. The encapsulant may also be applied in the form of conformal coatings containing nanoparticles that may be applied in thin layers that cover the LED, with the conformal coating and the LED then being covered by another encapsulant.

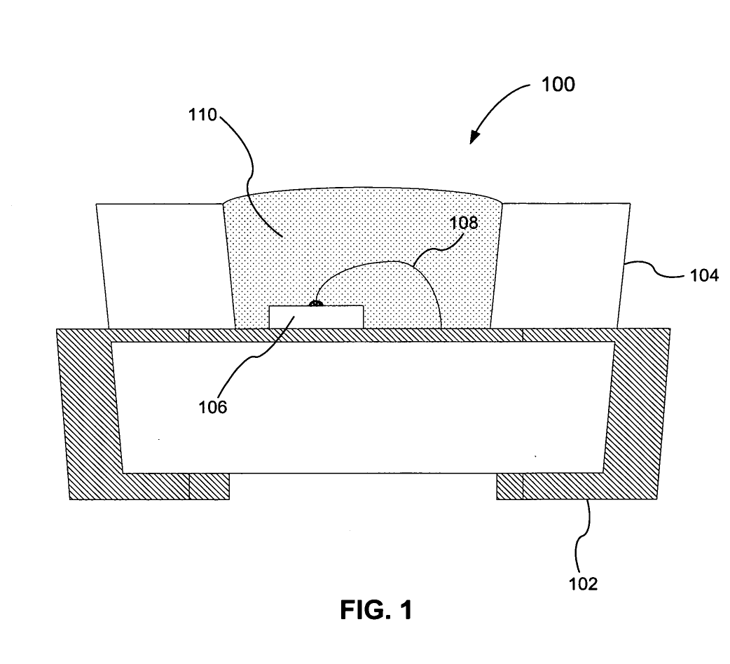

FIG. 1 shows a cross-sectional side view illustrating an example of an implementation of an LED device 100 having an encapsulant containing nanoparticles filling a concave base cavity in which an LED is placed. LED device 100 includes a casing 102 in which a concave base cavity 104 is positioned. An LED 106 is positioned in the concave base cavity 104, with a bonding wire 108 providing one of the two electrical connections for the LED device 100, for example, an anode connection. A cathode connection may then be located on the bottom surface of the LED 106, in the form of backside metallization (not shown), which may be implemented by attaching a conducting material to the bottom of LED 106.

In FIG. 1, the concave base cavity 104 is filled with an encapsulant containing nanoparticles 110, which encapsulant may be an epoxy resin or a silicone polymer having suspended nanoparticles. The nanoparticles may be selected from groups of either oxides or non-oxides, where the oxides include silica (SiO₂), titania (TiO₂), alumina (Al₂O₃), zirconia (ZrO₂), etc., and the non-oxides contain pure metals or metal borides, carbides and nitrides, such as titanium and its combinations (Ti, TiB₂, TiC, TiN, etc.) In the case of a silicone encapsulant, the concentration of the nanoparticles may be less than 1.0% of the silicone matrix. Also, the amount of nanoparticles suspended may be adjusted to improve the refractive index of the encapsulant 110 so as to improve the intensity of the light emitted by the LED device 100.

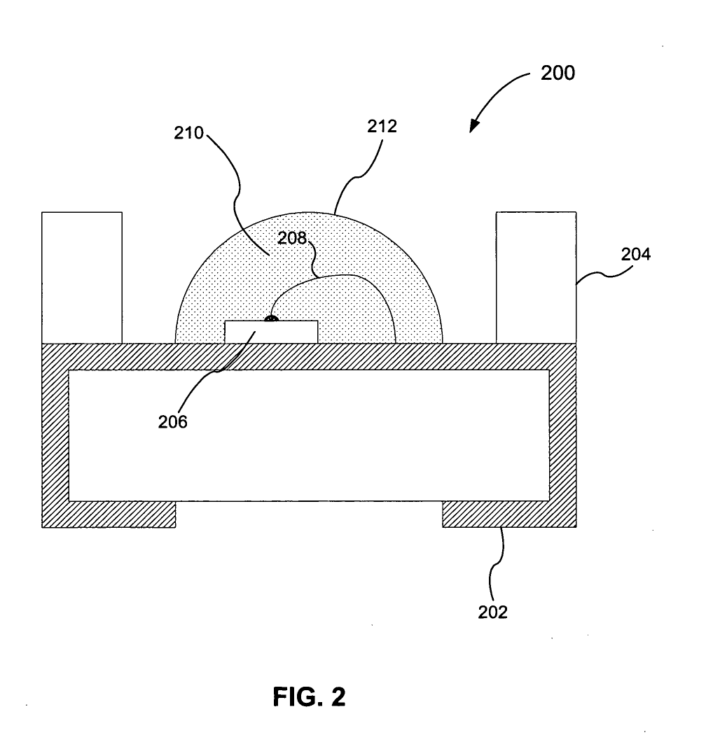

FIG. 2 shows a cross-sectional side view illustrating another example of an implementation of an LED device 200 having a dome 212 covering an LED 206 attached to a concave base cavity 204 where the dome 212 is filled with an encapsulant containing nanoparticles 210. As in FIG. 1, a bonding wire 208 provides one of the two electrical connections for the LED device 200, for example, an anode connection. In contrast to FIG. 1, a concave base cavity may not be entirely filled with an encapsulant but a lens 212, which may be transparent and which may also function as a collimating lens, is positioned over the LED 206 and filled with the encapsulant containing nanoparticles 210.

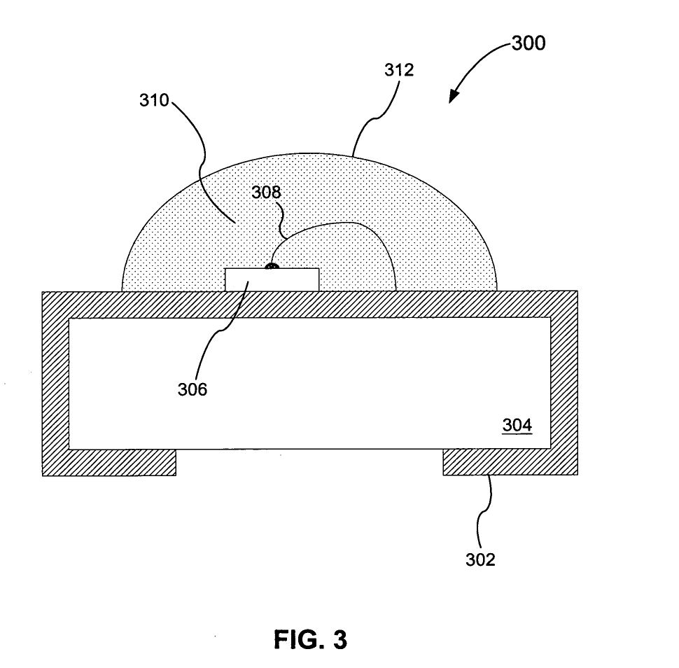

FIG. 3 shows a cross-sectional side view illustrating yet another example of an implementation of an LED device 300 having an encapsulant containing nanoparticles 310 filling a dome 312 covering an LED 306 attached to a substrate 304. The substrate 304 includes a casing 302. A bonding wire 308 provides one of the two electrical connections for the LED device 100, for example, an anode connection, and a cathode connection may then be located on the bottom surface of the LED 306, in the form of backside metallization (not shown), which may be implemented by attaching a conducting material to the bottom of LED 306.

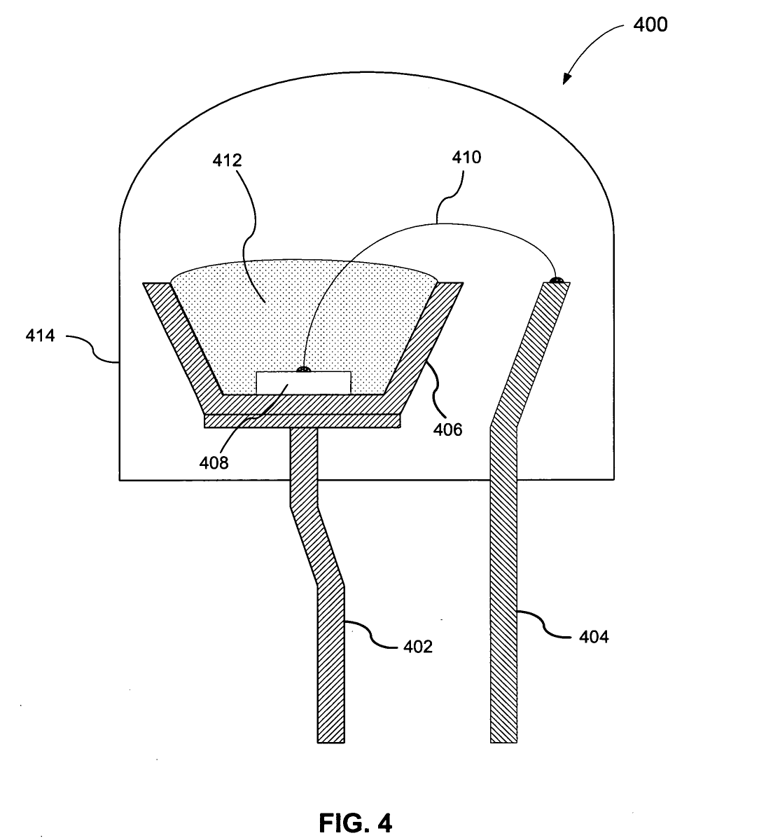

In FIG. 4, a cross-sectional side view illustrating yet another example of an LED device is shown. In FIG. 4, the LED device 400 includes a mount lead 402 and an inner lead 404. The mount lead 402 also includes a reflector cup 406, in which an LED 408 is attached. An electrode (not shown) of the LED 408 may be connected to the inner lead 404 by bonding wire 410, while the other electrode may be located on the bottom surface of the LED 408 and connected to the mount lead 402 by backside metallization (not shown). The reflector cup 404 is filled with an encapsulant containing nanoparticles 412, which may be an epoxy resin or a silicone polymer having suspended nanoparticles in accordance with the invention. The mount lead 402, the inner lead 404, and the reflector cup 406 are enclosed in a housing 414, which may include a metal can and a glass cover.

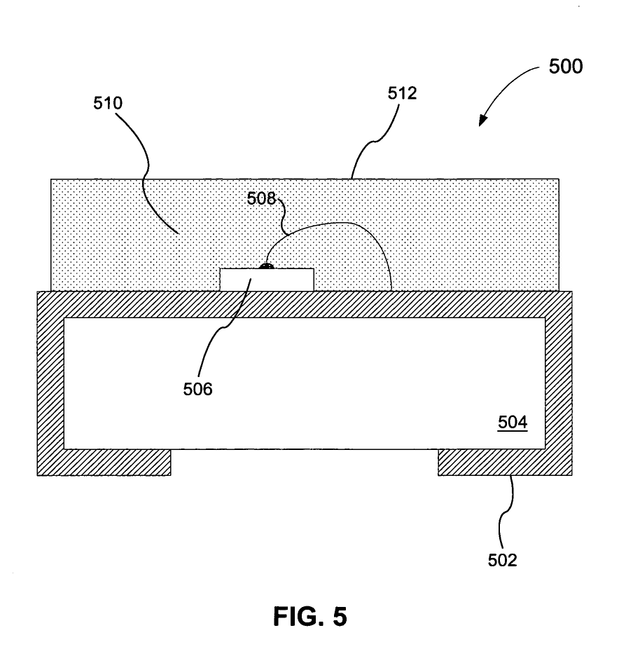

FIG. 5 shows a cross-sectional side view illustrating another example of an implementation of an LED device 500 having an encapsulant containing nanoparticles 510 that fills a shell 512 covering an LED 506 attached to a substrate 504. The substrate 504 includes a casing 502. A bonding wire 508 provides one of the two electrical connections for the LED device 500, for example, an anode connection, and a cathode connection may then be located on the bottom surface of the LED 506, in the form of backside metallization (not shown), which may be implemented by attaching a conducting material to the bottom of LED 506.

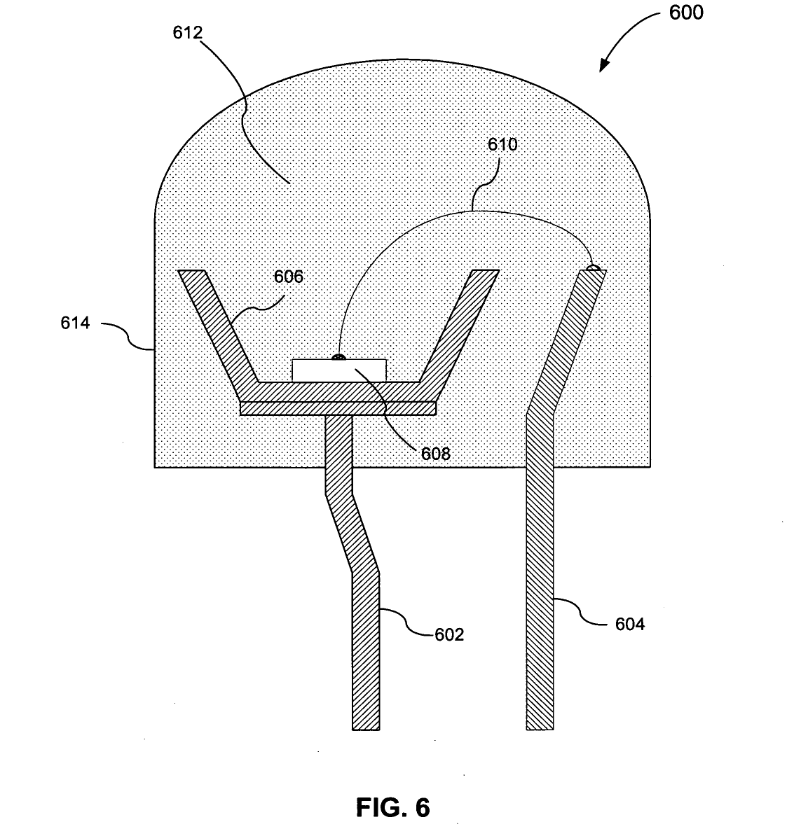

In FIG. 6, a cross-sectional side view illustrating another example of an LED device 600 that includes a mount lead 602 and an inner lead 406 is shown. The mount lead 602 also includes a reflector cup 606, in which an LED 608 is attached. An electrode (not shown) of the LED 408 may be connected to the inner lead 404 by bonding wire 410, while the other electrode may be located on the bottom surface of the LED 408 and connected to the mount lead 402 by backside metallization (not shown).

The entire package may be encapsulated within a shell 614, which may be glass or plastic, and an encapsulant containing nanoparticles 612 fills the entire shell 614. The encapsulant containing nanoparticles 612 may be an epoxy resin or a silicone polymer material with suspended nanoparticles, and both the shell 614 and the encapsulant containing nanoparticles 612 may be transparent or substantially optically transmissive with respect to the wavelength of the light produced by the LED 608.

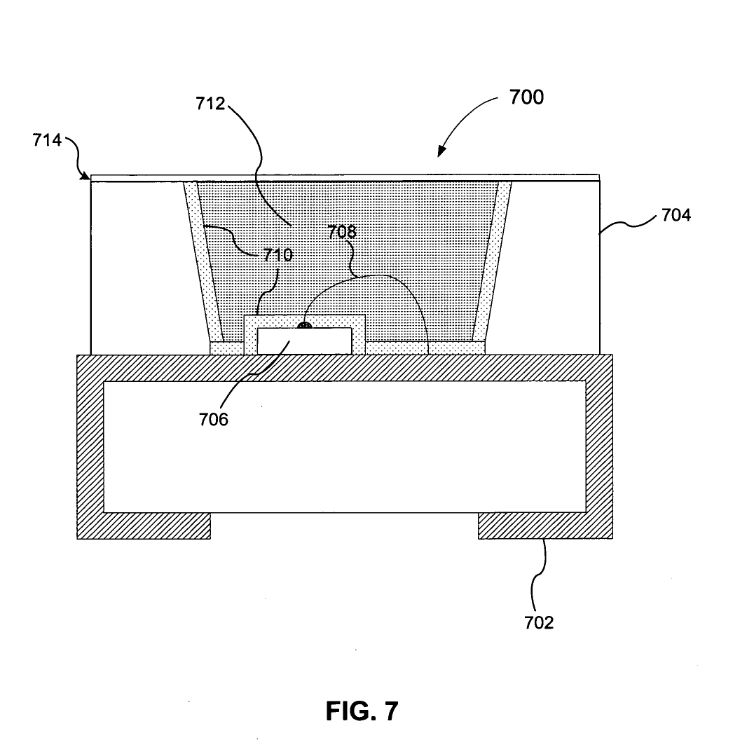

FIGS. 7, 8, 9, and 10 show examples of implementations of LED devices that utilize conformal coatings containing nanoparticles to cover the light source. In general, conformal coatings are materials applied in thin layers onto electronic devices and the materials used may be based on epoxies, silicones, acrylics, urethanes, or other similar materials. An example of such a process is Spin-on Glass (“SOG”), wherein the SOG material may be applied in liquid form over the LED. FIGS. 7, 8, 9, and 10 show various examples of implementations of LED devices where a coating of an SOG material, which may be an epoxy or a silicate, having suspended nanoparticles therein, is applied over an LED in a thin coating, which may be followed by the application of another encapsulant.

FIG. 7 shows a cross-sectional side view illustrating an example of an implementation of an LED device 700 having an encapsulant 712 filling a concave base cavity 704 in which an LED 706 is placed and then coated with a thin layer of an SOG material with nanoparticles 710. LED device 700 includes a casing 702 in which the concave base cavity 704 may be positioned. An LED 706 is positioned in the concave base cavity 704, with a bonding wire 708 providing one of the two electrical connections for the LED device 700, for example, an anode connection. A cathode connection may then be located on the bottom surface of the LED 706, in the form of backside metallization (not shown), which may be implemented by attaching a conducting material to the bottom of LED 706.

In FIG. 7, the inner surface of the concave base cavity 704, including the LED 706, is coated with a thin layer of a SOG material with nanoparticles 710 in accordance with the invention. The LED device 700 is then filled with an encapsulant 712, which may be an epoxy resin or a silicone polymer. The LED device may then be covered with a glass lid 714.

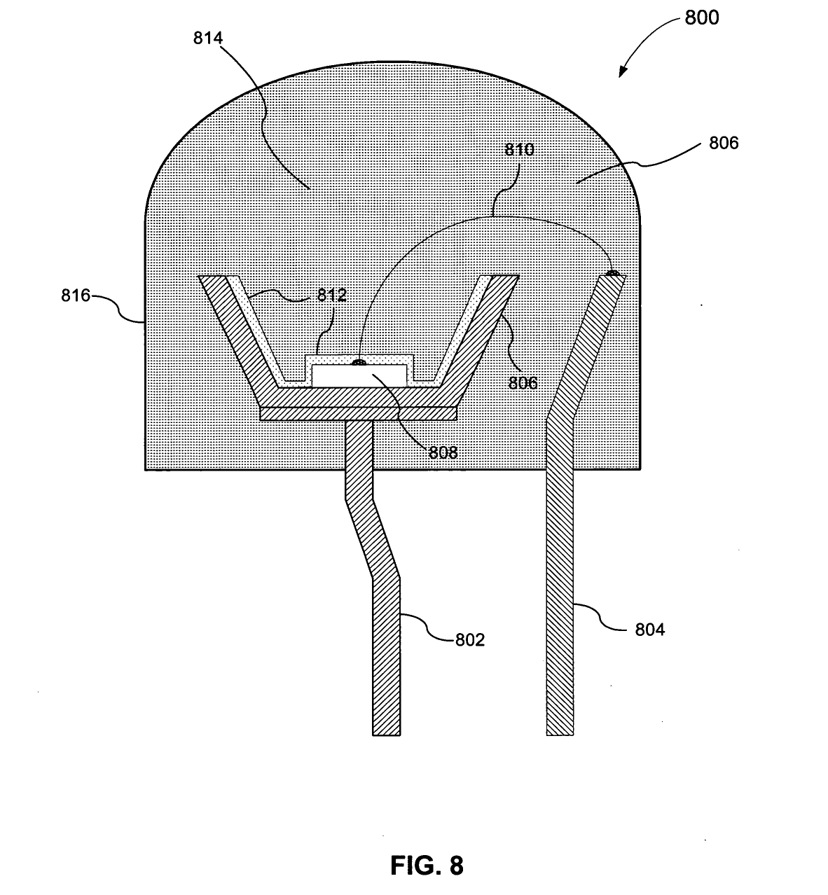

In FIG. 8, a cross-sectional side view illustrating another example of an LED device 800 that includes a mount lead 802 and an inner lead 804. The mount lead 802 also includes a reflector cup 806, in which an LED 808 is attached. An electrode (not shown) of the LED 808 may be connected to the inner lead 804 by bonding wire 810, while the other electrode may be located on the bottom surface of the LED 808 and connected to the mount lead 802 by backside metallization (not shown).

The inner surface of the reflector cup 806, including the LED 808, may be coated with a thin layer of an SOG material with nanoparticles 812 in accordance with the invention. The entire package may then be encapsulated within a shell 816, which may be glass or plastic, with the entire shell 816 being filled with an encapsulant 814. The encapsulant 814 may be an epoxy resin or a silicone polymer material, and both the shell 816 and the encapsulant 814 may be transparent or substantially optically transmissive with respect to the wavelength of the light produced by the LED 808.

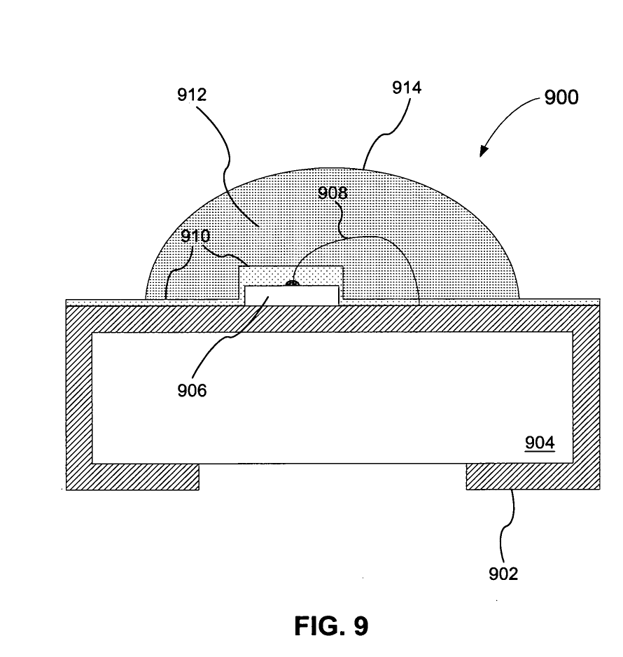

Turning to FIG. 9, a cross-sectional side view illustrating yet another example of an implementation of an LED device 900 having a dome 914 covering an LED 906 attached to a substrate 904 that may include a casing 902 is shown. A bonding wire 908 provides one of the two electrical connections for the LED device 900, for example, an anode connection, and a cathode connection may then be located on the bottom surface of the LED 906, in the form of backside metallization (not shown), which may be implemented by attaching a conducting material to the bottom of LED 906.

In FIG. 9, a conformal coating containing nanoparticles 910, which may be a SOG material with nanoparticles in accordance with the invention, is applied in a thin layer over the substrate 904, including the LED 906. The conformal coating containing nanoparticles 910 may have the effect of planarizing the surface of the substrate 904. After application of the conformal coating containing nanoparticles 910, a dome 914, which may be glass or plastic, is placed on the surface of the substrate 904 and is filled with an encapsulant 912, which may be an epoxy, a silicone, or any other suitable encapsulation material.

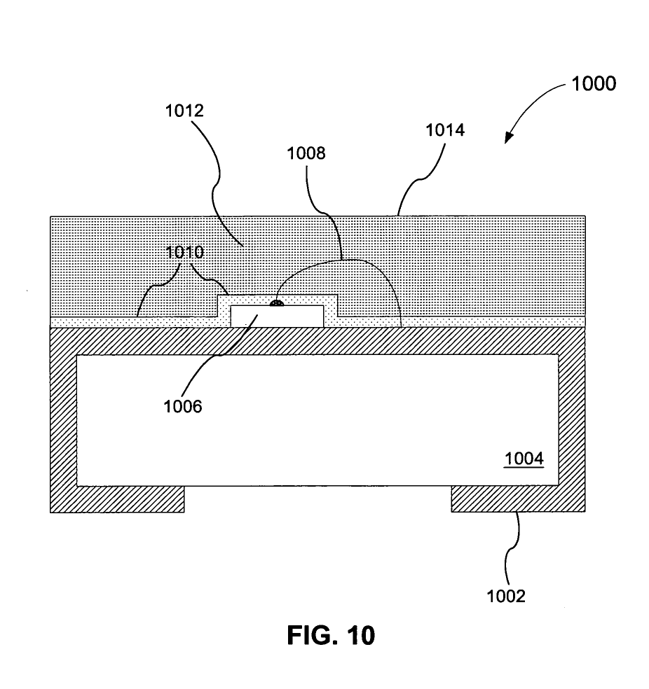

In FIG. 10, a cross-sectional side view illustrating yet another example of an implementation of an LED device 1000 having a shell 1014 covering an LED 1006 attached to a substrate 1004 is shown. LED device 1000 may also include a casing 1002. A bonding wire 1008 provides one of the two electrical connections for the LED device 1000, for example, an anode connection, and a cathode connection may then be located on the bottom surface of the LED 1006, in the form of backside metallization (not shown), which may be implemented by attaching a conducting material to the bottom of LED 1006.

In FIG. 10, a conformal coating containing nanoparticles 1010, which may be a SOG material with nanoparticles in accordance with the invention, is applied in a thin layer over the substrate 1004, including the LED 1006. The conformal coating 1010 may have the effect of planarizing the surface of the substrate 1004. After application of the conformal coating containing nanoparticles 1010, the substrate 1004 may be packaged in a shell 1014, which may be glass or plastic or a metal can, which is placed on and attached to the surface of the substrate 904. The package is filled with an encapsulant 1012, which may be an epoxy, a silicone, or any other suitable encapsulation material.

While the foregoing descriptions refer to the use of an LED, which may include a blue-light-emitting diode or an UV diode, the subject matter is not limited to such a device as a light source. Any semiconductor radiation source that could benefit from the functionality provided by the components described above may be implemented as the light source, including semiconductor laser diodes.

Moreover, it will be understood that the foregoing description of numerous implementations has been presented for purposes of illustration and description. It is not exhaustive and does not limit the claimed inventions to the precise forms disclosed. Modifications and variations are possible in light of the above description or may be acquired from practicing the invention. The claims and their equivalents define the scope of the invention.

What is claimed:

1. An electroluminescent device capable of emitting visible light, the electroluminescent device comprising:
a semiconductor radiation source; and
an encapsulant that is applied to the surface of the semiconductor radiation source, wherein the encapsulant contains a plurality of nanoparticles suspended therein selected from groups consisting of oxides and non-oxides.

2. The electroluminescent device of claim 1, wherein the semiconductor radiation source includes at least one light-emitting diode (“LED”).

3. The electroluminescent device of claim 2, wherein the nanoparticles are selected from a group consisting of silica (SiO₂), titania (TiO₂), alumina (Al₂O₃), and zirconia (ZrO₂).

4. The electroluminescent device of claim 3, wherein the average particle size of nanoparticles is 80-150 nm in diameter.

5. The electroluminescent device of claim 2, wherein the nanoparticles are selected from a group consisting of Ti, TiB₂, TiC, and TiN.

6. The electroluminescent device of claim 5, wherein the average particle size of nanoparticles is 40-100 nm in diameter.

7. The electroluminescent device of claim 2, wherein the encapsulant is applied to the surface of the at least one LED by at least one application of a conformal coating.

8. The electroluminescent device of claim 7, wherein the conformal coating includes a Spin-on Glass (“SOG”) material that contains the nanoparticles.

9. A method for producing an electroluminescent device that utilizes a semiconductor radiation source and an encapsulant, the method comprising:
suspending nanoparticles in the encapsulant;
applying the encapsulant to cover the surface of the semiconductor radiation source; and
packaging the semiconductor radiation source and the encapsulant in the electroluminescent device.

10. The method of claim 9, wherein the encapsulant is an epoxy resin, a silicone system, an acrylic, or a urethane.

11. The method of claim 10, wherein the semiconductor radiation source includes at least one LED.

12. The method of claim 11, wherein the nanoparticles are selected from a group consisting of silica (SiO₂), titania (TiO₂), alumina (Al₂O₃), zirconia (ZrO₂), Ti, TiB₂, TiC, and TiN.

13. The method of claim 12, further including:
positioning the at least one LED in a concave base cavity;
filling the concave base cavity with the encapsulant; and
packaging the concave base cavity with the at least one LED and the encapsulant in the electroluminescent device.

14. The method of claim 13, wherein packaging the concave base cavity further includes filling the electroluminescent device with the encapsulant.

15. The method of claim 12, wherein applying the encapsulant further includes applying the encapsulant in the form of a conformal coating.

16. The method of claim 15, wherein applying the encapsulant in the form of a conformal coating further includes:
suspending the nanoparticles in an SOG material; and
applying the SOG material in a liquid form to cover the at least one LED.

17. An encapsulant for use in an electroluminescent device capable of emitting visible light, the encapsulant comprising:
an epoxy resin, a silicone system, an acrylic, or a urethane; and
nanoparticles selected from groups consisting of oxides and non-oxides, wherein the nanoparticles each have a diameter of less than 165 nm, and are suspended in the encapsulant.

18. The encapsulant of claim 17, wherein the nanoparticles are selected from a group consisting of silica (SiO₂), titania (TiO₂), alumina (Al₂O₃), zirconia (ZrO₂), Ti, TiB₂, TiC, and TiN.

19. The encapsulant of claim 18, wherein the encapsulant is applied to cover a light source positioned in a concave base cavity of the electroluminescent device.

20. The encapsulant of claim 19, wherein the encapsulant is further applied in the form of a conformal coating.
